(19) United States
(12) Patent Application Publication
(10) Pub. No.: US 2024/0006423 A1
(43) Pub. Date: Jan. 4, 2024

(54) Transistor and Display Device

(71) Applicant: LG Display Co., Ltd., Seoul (KR)

(72) Inventors: Seonghwan Hwang, Seoul (KR); ByeongUk Gang, Paju-si (KR)

(21) Appl. No.: 18/213,250

(22) Filed: Jun. 22, 2023

(30) Foreign Application Priority Data
Jun. 30, 2022 (KR) 10-2022-0080507

(51) Int. Cl. H01L 27/12

(52) U.S. Cl. CPC H01L 27/1255; H01L 27/124; H01L 27/1251

(57) ABSTRACT

Embodiments of the present disclosure relate to a transistor and a display device, and more particularly, to a display device including a substrate, a first capacitor electrode on the substrate, a first buffer layer on the first capacitor electrode, a second capacitor electrode located on the first buffer layer and overlapping at least a portion of the first capacitor electrode, a second buffer layer on the second capacitor electrode, an active layer on the second buffer layer, a gate insulating film on the active layer, and a source electrode located on the gate insulating film and overlapping at least a portion of the active layer, and the active layer overlaps at least a portion of an overlapping region between the first capacitor electrode and the second capacitor electrode to provide a sub-pixel having a high aperture ratio structure, thereby providing a high-resolution image.

### CROSS REFERENCE TO RELATED APPLICATION

This application claims priority from Republic of Korea Patent Application No. 10-2022-0080507, filed on Jun. 30, 2022, which is hereby incorporated by reference in its entirety.

### BACKGROUND

### 1. Field of Technology

Embodiments of the present disclosure relate to a transistor and a display device.

### 2. Description of the Prior Art

Display devices may include a driving transistor and a storage capacitor for each sub-pixel. An aperture ratio of the sub-pixel may be changed according to the structure of the sub-pixel, and an image quality or resolution of a display panel may be changed according to the aperture ratio of the sub-pixel.

These days, a higher resolution is required in display panels. In order to design a high-resolution display panel as described above, it is absolutely necessary to increase an aperture ratio of each sub-pixel.

However, it is very difficult to design a sub-pixel structure to increase the aperture ratio of the sub-pixel because the number or type of elements (e.g., transistors, storage capacitors, and light-emitting elements) included in each sub-pixel is fixed.

### SUMMARY

Embodiments of the present disclosure may provide a display device including a sub-pixel having a high aperture ratio structure.

Embodiments of the present disclosure may provide a transistor enabling a high aperture ratio structure of a sub-pixel and a display device including the same.

Embodiments of the present disclosure may provide a display device capable of displaying a high-resolution image.

A display device according to embodiments of the present disclosure includes a substrate, a first capacitor electrode on the substrate, a first buffer layer on the first capacitor electrode, a second capacitor electrode located on the first buffer layer and overlapping at least a portion of the first capacitor electrode, a second buffer layer on the second capacitor electrode, an active layer on the second buffer layer, a gate insulating film on the active layer, and a source electrode located on the gate insulating film and overlapping at least a portion of the active layer.

The active layer may overlap at least a portion of an overlapping region between the first capacitor electrode and the second capacitor electrode.

The active layer may include a first region, a second region, and a third region between the first region and the second region.

The second capacitor electrode may be located below the third region and overlap the third region. An image data signal may be applied to the second capacitor electrode. The second capacitor electrode may be a gate electrode of the driving transistor.

The source electrode may overlap at least a portion of the overlapping region between the first capacitor electrode and the second capacitor electrode.

The source electrode may overlap a channel region of the active layer.

The source electrode may be electrically connected to the first capacitor electrode.

The display device according to embodiments of the present disclosure may further include a protective film on the source electrode, an overcoat layer on the protective film, and a pixel electrode electrically connected to the source electrode through a first contact hole of the protective film and the overcoat layer.

The first contact hole may overlap the active layer.

The first contact hole may overlap a channel region of the active layer.

The display device according to embodiments of the present disclosure may further include a first auxiliary layer on the first region and a second auxiliary layer on the second region.

As an example, the active layer may include a first semiconductor material, each of the first auxiliary layer and the second auxiliary layer may include a second semiconductor material different from the first semiconductor material, and a mobility of the first semiconductor material may be higher than a mobility of the second semiconductor material.

In another embodiment, a transistor according to embodiments of the present disclosure includes an auxiliary source electrode on a substrate, a source electrode located over the auxiliary source electrode and spaced apart from the auxiliary source electrode, an active layer located between the auxiliary source electrode and the source electrode and including a first region, a second region, and a third region between the first region and the second region, and a gate electrode located between the auxiliary source electrode and the active layer.

The first region may be electrically connected to the auxiliary source electrode and the source electrode, the second region may be electrically connected to a drain electrode or may correspond to the drain electrode, the third region may overlap the gate electrode, and at least a portion of the auxiliary source electrode may overlap the gate electrode.

At least a portion of the auxiliary source electrode may overlap the source electrode.

A voltage difference between the auxiliary source electrode and the gate electrode may be maintained for a predetermined time.

In another embodiment, a display device according to embodiments of the present disclosure includes a substrate, a first capacitor electrode on the substrate, a first buffer layer on the first capacitor electrode, a second capacitor electrode located on the first buffer layer and overlapping at least a portion of the first capacitor electrode, a second buffer layer on the second capacitor electrode, an active layer on the second buffer layer, a gate insulating film on the active layer, a source electrode located on the gate insulating film and overlapping at least a portion of the active layer, an overcoat layer on the source electrode, and a pixel electrode electrically connected to the source electrode through a first contact hole of the overcoat layer.

In the display device according to embodiments of the present disclosure, the first contact hole may overlap the active layer.

In the display device according to embodiments of the present disclosure, the first contact hole may overlap a channel region of the active layer.

In the display device according to embodiments of the present disclosure, the active layer may overlap at least a portion of an overlapping region between the first capacitor electrode and the second capacitor electrode.

In another embodiment, a display device according to embodiments of the present disclosure includes a substrate, a driving transistor disposed on the substrate and including a first electrode, a second electrode, a third electrode, and an active layer, a pixel electrode electrically connected to the first electrode in a first contact hole, and a storage capacitor between the first electrode and the third electrode.

In the display device according to embodiments of the present disclosure, the storage capacitor, the active layer, and the first contact hole may overlap in a vertical direction.

### Advantageous Effects

According to embodiments of the present disclosure, a sub-pixel having a high aperture ratio structure can be provided.

According to embodiments of the present disclosure, an aperture ratio of a sub-pixel can be increased through a bottom gate structure of a driving transistor.

According to embodiments of the present disclosure, an aperture ratio of a sub-pixel can be increased through a structure in which a storage capacitor is formed below a driving transistor.

According to embodiments of the present disclosure, an aperture ratio of a sub-pixel can be increased through a structure in which a source electrode of a driving transistor and a pixel electrode are connected to each other at an upper portion of the driving transistor.

According to embodiments of the present disclosure, a transistor having a unique structure allowing an aperture ratio of a sub-pixel to be increased can be provided.

According to embodiments of the present disclosure, a high-resolution image can be provided through a high aperture ratio structure of a sub-pixel.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a system configuration diagram of a display device according to embodiments of the present disclosure;

FIG. 2 is an equivalent circuit diagram of a sub-pixel of the display device according to embodiments of the present disclosure;

FIG. 3 is another equivalent circuit diagram of the sub-pixel of the display device according to embodiments of the present disclosure;

FIG. 4 is an equivalent circuit diagram of the sub-pixel, when a light shield is added, in the display device according to embodiments of the present disclosure;

FIG. 5 is a plan view of the sub-pixel in the display device according to embodiments of the present disclosure;

FIG. 6 is a diagram schematically illustrating a high aperture ratio structure of a sub-pixel, in the display device according to embodiments of the present disclosure;

FIG. 7 is a plan view of a display panel in a region in which the sub-pixel having a high aperture ratio structure according to embodiments of the present disclosure is disposed;

FIG. 8 is a cross-sectional view taken along line A-A′ of FIG. 7 according to embodiments of the present disclosure;

FIG. 9 illustrates a cross-sectional structure of a scanning transistor, in the sub-pixel having a high aperture ratio structure according to embodiments of the present disclosure; and

FIG. 10 illustrates a cross-sectional structure of a sensing transistor, in the sub-pixel having a high aperture ratio structure according to embodiments of the present disclosure.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the present disclosure will be described in detail with reference to the accompanying drawings.

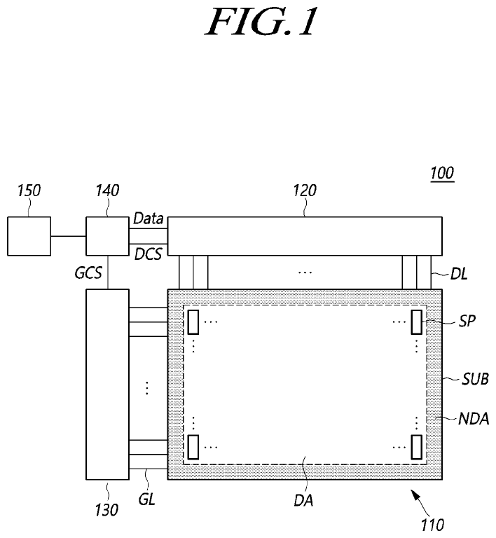

FIG. 1 is a system configuration diagram of a display device 100 according to embodiments of the present disclosure.

Referring to FIG. 1, the display device 100 according to embodiments of the present disclosure may include a display panel 110 and a driving circuit for driving the display panel 110.

The driving circuit may include a data driving circuit 120, a gate driving circuit 130, and the like, and may further include a controller 140 that controls the data driving circuit 120 and the gate driving circuit 130.

The display panel 110 may include a substrate SUB and signal lines (also referred to as wiring) such as a plurality of data lines DL and a plurality of gate lines GL disposed on the substrate SUB. The display panel 110 may include a plurality of sub-pixels SP connected to the plurality of data lines DL and the plurality of gate lines GL.

The display panel 110 may include a display area DA in which an image is displayed and a non-display area NDA in which an image is not displayed, and which is located around the display area DA. In the display panel 110, the plurality of sub-pixels SP for displaying an image may be disposed in the display area DA, and in the non-display area NDA, the driving circuits 120, 130, and 140 may be electrically connected or the driving circuits 120, 130, and 140 may be mounted, and a pad part to which an integrated circuit, a printed circuit, or the like is connected may be disposed.

The data driving circuit 120 is a circuit for driving the plurality of data lines DL and may supply data signals to the plurality of data lines DL. The gate driving circuit 130 is a circuit for driving the plurality of gate lines GL, and may supply gate signals to the plurality of gate lines GL.

The controller may receive input image data and various timing signals from a host system 150. The controller may generate various gate control signals GCS and various data control signals DCS using various timing signals received from the host system 150. For example, various timing signals may include a vertical synchronization signal (Vsync), a horizontal synchronization signal (Hsync), an input data enable (DE) signal, a clock signal, and the like. The controller 140 may supply a data control signal DCS to the data driving circuit 120 in order to control an operation timing of the data driving circuit 120. The controller 140 may supply a gate control signal GCS for controlling an operation timing of the gate driving circuit 130 to the gate driving circuit 130.

The controller 140 may control such that a scanning operation starts according to a timing implemented in each frame, convert input image data, which is input from the host system 150, according to a data signal format used by the data driving circuit 120 and supply image data Data, which is the converted data, to the data driving circuit 120, and control such that data driving is performed at an appropriate time according to a scanning timing.

In order to control the gate driving circuit 130, the controller 140 may output various types of gate control signals GCS including a gate start pulse GSP, a gate shift clock GSC, a gate output enable signal GOE, and the like.

In order to control the data driving circuit 120, the controller 140 may output various types of data control signals DCS including a source start pulse SSP, a source sampling clock SSC, a source output enable signal SOE, and the like.

The controller 140 may be implemented as a separate component from the data driving circuit 120 or implemented as an integrated circuit by being integrated with the data driving circuit 120.

The data driving circuit 120 receives the image data Data from the controller 140 and supplies a data voltage to the plurality of data lines DL to drive the plurality of data lines DL. Here, the data driving circuit 120 is also referred to as a source driving circuit.

The data driving circuit 120 may include one or more source driver integrated circuits (SDIC).

For example, each SDIC may be connected to the display panel 110 by a tape-automated bonding (TAB) method, may be connected to a bonding pad of the display panel 110 by a chip-on-glass (COG) method or a chip-on-panel (COP) method, or may be connected to the display panel 110 by a chip-on-film (COF) method.

The gate driving circuit 130 may output a gate signal of a turn-on level voltage or a gate signal of a turn-off level voltage under the control of the controller 140. The gate driving circuit 130 may sequentially drive the plurality of gate lines GL by sequentially supplying the gate signal of the turn-on level voltage to the plurality of gate lines GL.

The gate driving circuit 130 may be connected to the display panel 110 by a TAB method, may be connected to the bonding pad of the display panel 110 by a COG method or a COP method, or may be connected to the display panel 110 by a COF method. Alternatively, the gate driving circuit 130 may be formed in the non-display area NDA of the display panel 110 in a gate-in-panel (GIP) type. The gate driving circuit 130 may be disposed on the substrate SUB or may be connected to the substrate SUB. That is, in a case in which the gate driving circuit 130 is a GIP type, the gate driving circuit 130 may be disposed in the non-display area NDA of the substrate SUB. In a case in which the gate driving circuit 130 is a COG type, a COF type, or the like, the gate driving circuit 130 may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be disposed not to overlap the sub-pixels SP, or may also be disposed to partially or entirely overlap the sub-pixels SP.

When a specific gate line GL is opened by the gate driving circuit 130, the data driving circuit 120 may convert the image data Data, which is received from the controller 140, into an analog-type data voltage and supply the converted analog-type data voltage to the plurality of data lines DL.

The data driving circuit 120 may be connected to one side (e.g., an upper side or a lower side) of the display panel 110. Depending on a driving method, a panel design method, or the like, the data driving circuit 120 may be connected to both sides (e.g., the upper side and the lower side) of the display panel 110 or may also be connected to two or more side surfaces of four side surfaces of the display panel 110.

The gate driving circuit 130 may be connected to one side (e.g., a left side or a right side) of the display panel 110. Depending on a driving method, a panel design method, or the like, the gate driving circuit 130 may be connected to both sides (e.g., the left side and the right side) of the display panel 110 or may also be connected to two or more side surfaces of the four side surfaces of the display panel 110.

The controller 140 may be a timing controller used in a conventional display technique or a control device that may further perform other control functions in addition to the function of the timing controller, may be a control device different from the timing controller, or may be a circuit in the control device. The controller 140 may be implemented as various circuits or electronic components, such as integrated circuits (ICs), field-programmable gate arrays (FPGAs), application-specific integrated circuits (ASICs), processors, or the like.

The controller 140 may be mounted on a printed circuit board, a flexible printed circuit board, or the like, and may be electrically connected to the data driving circuit 120 and the gate driving circuit 130 through the printed circuit board, the flexible printed circuit board, or the like.

The display device 100 according to embodiments of the present disclosure may be a display including a backlight unit such as a liquid-crystal display device, and may be a self-emissive display such as an organic light-emitting diode (OLED) display, a quantum dot display, or a micro light-emitting diode (LED) display.

When the display device 100 according to embodiments of the present disclosure is an OLED display, each of the sub-pixels SP may include an OLED, which emits light by itself, as a light-emitting device. When the display device 100 according to embodiments of the present disclosure is a quantum dot display, each of the sub-pixels SP may include a light-emitting device made of a quantum dot, which is a semiconductor crystal that emits light by itself. When the display device 100 according to embodiments of the present disclosure is a micro-LED display, each of the sub-pixels SP may include a micro LED, which emits light by itself and is made based on an inorganic material, as a light-emitting device.

The display panel 110 according to embodiments of the present disclosure may have a top emission structure or a bottom emission structure, and in some cases, may have a double-sided emission structure.

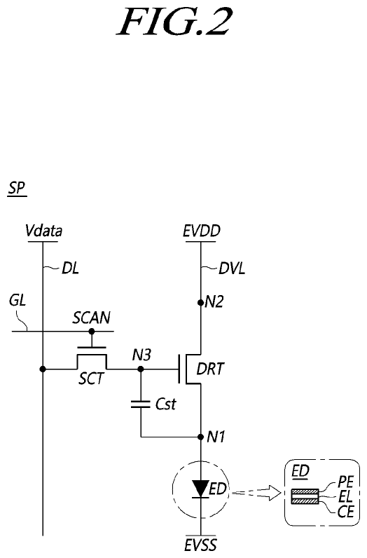

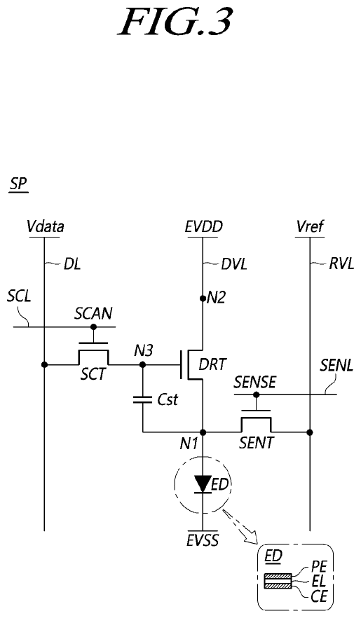

FIG. 2 is an equivalent circuit diagram of the sub-pixel SP of the display device 100 according to embodiments of the present disclosure, and FIG. 3 is another equivalent circuit diagram of the sub-pixel SP of the display device 100 according to embodiments of the present disclosure.

Referring to FIG. 2, each of the plurality of sub-pixels SP disposed in the display panel 110 of the display device 100 according to embodiments of the present disclosure may include a light-emitting device ED, a driving transistor DRT, a scanning transistor SCT, and a storage capacitor Cst.

Referring to FIG. 2, the light-emitting device ED may include a pixel electrode PE, a common electrode CE, and a light-emitting layer EL located between the pixel electrode PE and the common electrode CE.

The pixel electrode PE of the light-emitting device ED may be an electrode disposed for each sub-pixel SP, and the common electrode CE may be an electrode commonly disposed in all sub-pixels SP. Here, the pixel electrode PE may be an anode and the common electrode CE may be a cathode. In contrast, the pixel electrode PE may be a cathode and the common electrode CE may be an anode.

For example, the light-emitting device ED may be an OLED, an LED, a quantum dot light-emitting device, or the like.

The driving transistor DRT is a transistor for driving the light-emitting device ED, and may include a first node N1, a second node N2, a third node N3, and the like. Here, the first node N1 may also be referred to as a first electrode, the second node N2 may also be referred to as a second electrode, and the third node N3 may also be referred to as a third electrode.

The first node N1 of the driving transistor DRT may be a source node (source electrode) or a drain node (drain electrode) of the driving transistor DRT, and may be electrically connected to the pixel electrode PE of the light-emitting device ED. The second node N2 of the driving transistor DRT may be the drain node (drain electrode) or the source node (source electrode) of the driving transistor DRT, and may be electrically connected to a driving voltage line DVL through which a driving voltage EVDD is supplied. The third node N3 of the driving transistor DRT may be a gate node (gate electrode) of the driving transistor DRT and may be electrically connected to a source node or a drain node of the scanning transistor SCT.

The scanning transistor SCT may be controlled by a scanning gate signal SCAN, which is a type of gate signal, and may be connected between the third node N3 of the driving transistor DRT and the data line DL. In other words, the scanning transistor SCT may be turned on or off according to the scanning gate signal SCAN supplied through a scanning gate line SCL, which is a type of the gate line GL, and may control a connection between the data line DL and the third node N3 of the driving transistor DRT.

The scanning transistor SCT may be turned on by the scanning gate signal SCAN having the turn-on level voltage, and may transmit a data voltage Vdata, which is supplied through the data line DL, to the third node N3 of the driving transistor DRT.

Here, when the scanning transistor SCT is an n-type transistor, the turn-on level voltage of the scanning gate signal SCAN may be a high-level voltage. When the scanning transistor SCT is a p-type transistor, the turn-on level voltage of the scanning gate signal SCAN may be a low-level voltage.

The storage capacitor Cst may be connected between the third node N3 and the first node N1 of the driving transistor DRT. The storage capacitor Cst is charged with an amount of electric charge corresponding to a voltage difference between both ends thereof and serves to maintain the voltage difference between both ends thereof during a predetermined frame time. Accordingly, light may be emitted from the corresponding sub-pixel SP during the predetermined frame time.

Referring to FIG. 3, each of the plurality of sub-pixels SP disposed in the display panel 110 of the display device 100 according to embodiments of the present disclosure may further include a sensing transistor SENT.

The sensing transistor SENT may be controlled by a sensing gate signal SENSE, which is a type of gate signal, and may be connected between the first node N1 of the driving transistor DRT and a reference voltage line RVL. In other words, the sensing transistor SENT may be turned on or off according to the sensing gate signal SENSE supplied through a sensing gate line SENL, which is another type of the gate line GL, and may control a connection between the reference voltage line RVL and the first node N1 of the driving transistor DRT.

The sensing transistor SENT may be turned on by the sensing gate signal SENSE having the turn-on level voltage, and may transmit a reference voltage Vref, which is supplied through the reference voltage line RVL, to the first node N1 of the driving transistor DRT.

Further, the sensing transistor SENT may be turned on by the sensing gate signal SENSE having the turn-on level voltage and may transmit a voltage at the first node N1 of the driving transistor DRT to the reference voltage line RVL.

Here, when the sensing transistor SENT is an n-type transistor, the turn-on level voltage of the sensing gate signal SENSE may be a high-level voltage. When the sensing transistor SENT is a p-type transistor, the turn-on level voltage of the sensing gate signal SENSE may be a low-level voltage.

The function of the sensing transistor SENT that transmits the voltage at the first node N1 of the driving transistor DRT to the reference voltage line RVL may be used when driven to sense a characteristic value of the sub-pixel SP. In this case, the voltage transmitted to the reference voltage line RVL may be a voltage for calculating the characteristic value of the sub-pixel SP or a voltage in which the characteristic value of the sub-pixel SP is reflected.

Each of the driving transistor DRT, the scanning transistor SCT, and the sensing transistor SENT may be an n-type transistor or a p-type transistor. In the present disclosure, for convenience of description, it is assumed that each of the driving transistor DRT, the scanning transistor SCT, and the sensing transistor SENT is the n-type transistor.

The storage capacitor Cst may be an external capacitor intentionally designed to be located outside the driving transistor DRT, rather than a parasitic capacitor (e.g., Cgs or Cgd), which is an internal capacitor that is present between the gate node and the source node (or drain node) of the driving transistor DRT.

The scanning gate line SCL and the sensing gate line SENL may be different gate lines GL. In this case, the scanning gate signal SCAN and the sensing gate signal SENSE may be separate gate signals, and an on-off timing of the scanning transistor SCT and an on-off timing of the sensing transistor SENT in one sub-pixel SP may be independent. That is, the on-off timing of the scanning transistor SCT and the on-off timing of the sensing transistor SENT in one sub-pixel SP may be the same as or different from each other.

Alternatively, the scanning gate line SCL and the sensing gate line SENL may be the same gate line GL. That is, a gate node of the scanning transistor SCT and a gate node of the sensing transistor SENT in one sub-pixel SP may be connected to one gate line GL. In this case, the scanning gate signal SCAN and the sensing gate signal SENSE may be the same gate signal, and the on-off timing of the scanning transistor SCT and the on-off timing of the sensing transistor SENT in one sub-pixel SP may be the same.

The structures of the sub-pixel SP shown in FIGS. 2 and 3 are merely examples and may be variously modified to further include one or more transistors or further include one or more capacitors.

Further, in FIGS. 2 and 3, the structures of the sub-pixels have been described on the assumption that the display device 100 is a self-emissive display device, but when the display device 100 is a liquid crystal display device, each sub-pixel SP may include a transistor, a pixel electrode, and the like.

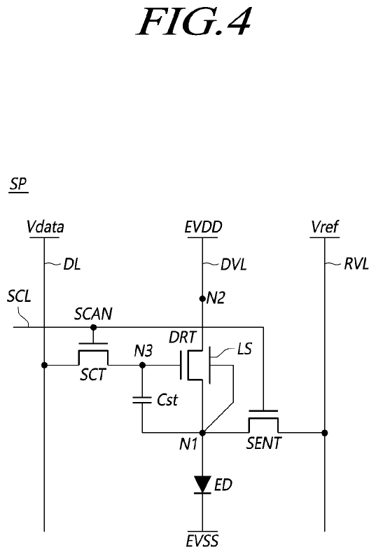

FIG. 4 is an equivalent circuit diagram of the sub-pixel SP when a light shield LS is added, in the display device 100 according to embodiments of the present disclosure.

Referring to FIG. 4, in the sub-pixel SP of the display device 100 according to embodiments of the present disclosure, the driving transistor DRT may have a unique characteristic value such as a threshold voltage, mobility, or the like. When the unique characteristic value of the driving transistor DRT is changed, a current driving capability (current supply performance) of the driving transistor DRT may be changed so that light emission characteristics of the corresponding sub-pixel SP may also be changed.

Element characteristics (e.g., a threshold voltage, mobility, or the like) of the driving transistor DRT may be changed as a driving time of the driving transistor DRT elapses. In addition, when light is irradiated onto the driving transistor DRT, in particular, when light is irradiated onto a channel region of the driving transistor DRT, the element characteristics (e.g., a threshold voltage, mobility, or the like) of the driving transistor DRT may be changed.

Accordingly, as shown in FIG. 4, the light shield LS may be formed in the vicinity of the driving transistor DRT to reduce a change (e.g., a threshold voltage change, a mobility change, or the like) in the element characteristics of the driving transistor DRT. For example, the light shield LS may be formed below the channel region of the driving transistor DRT.

Meanwhile, the light shield LS may be formed below the channel region of the driving transistor DRT and may serve as a body of the driving transistor DRT, in addition to serving to block light.

A body effect may occur in the driving transistor DRT, and the light shield LS serving as a body of the driving transistor DRT may be electrically connected to the first node N1 of the driving transistor DRT in order to reduce the influence of the body effect. Here, the first node N1 of the driving transistor DRT may be the source node of the driving transistor DRT.

Meanwhile, the light shield LS may be disposed not only below the channel region of the driving transistor DRT but also below a channel region of another transistor (e.g., the SCT or the SENT).

In the display area DA of the display panel 110 according to embodiments of the present disclosure, the transistors DRT, SCT, and SENT may be disposed for each of the sub-pixels SP. When the gate driving circuit 130 is formed in a GIP type in the non-display area NDA of the display panel 110 according to embodiments of the present disclosure, a plurality of transistors included in the gate driving circuit 130 of the GIP type may be disposed in the non-display area NDA of the display panel 110.

As described above, the scanning gate line SCL and the sensing gate line SENL may be different gate lines GL. In this case, the scanning gate signal SCAN and the sensing gate signal SENSE may be separate gate signals, and an on-off timing of the scanning transistor SCT and an on-off timing of the sensing transistor SENT in one sub-pixel SP may be independent. That is, the on-off timing of the scanning transistor SCT and the on-off timing of the sensing transistor SENT in one sub-pixel SP may be the same as or different from each other.

Alternatively, as shown in FIG. 4, the scanning gate line SCL and the sensing gate line SENL may be the same gate line GL. That is, a gate node of the scanning transistor SCT and a gate node of the sensing transistor SENT in one sub-pixel SP may be connected to the scanning gate line SCL, which is one gate line GL. In this case, the scanning gate signal SCAN and the sensing gate signal SENSE may be the same gate signal, and the on-off timing of the scanning transistor SCT and the on-off timing of the sensing transistor SENT in one sub-pixel SP may be the same. In the following description, for convenience of description, as shown in FIG. 4, a case in which one scanning gate line SCL is commonly connected to the gate node of the scanning transistor SCT and the gate node of the sensing transistor SENT, and one scanning gate signal SCAN is commonly applied to the gate node of the scanning transistor SCT and the gate node of the sensing transistor SENT will be described as an example.

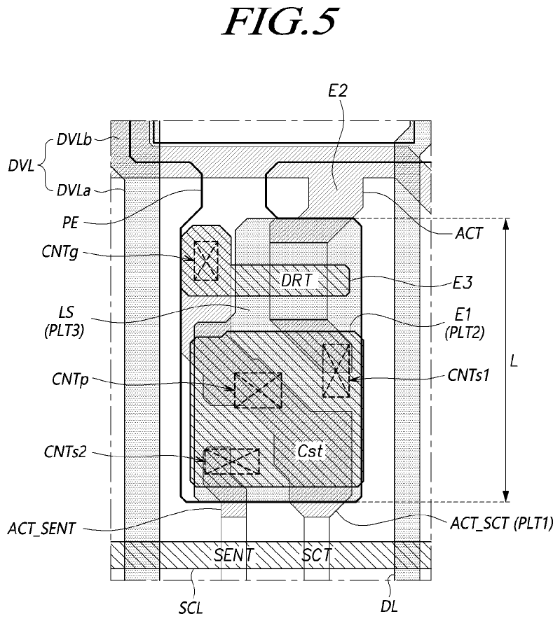

FIG. 5 is a plan view of the sub-pixel SP, in the display device 100 according to embodiments of the present disclosure. However, an example is described in which the sub-pixel SP has the structure shown in FIG. 4.

Referring to FIG. 5, the driving transistor DRT, the scanning transistor SCT, the sensing transistor SENT, and the storage capacitor Cst may be disposed in a region in which one sub-pixel SP is disposed.

All of the driving transistor DRT, the scanning transistor SCT, and the sensing transistor SENT illustrated in FIG. 5 may be top-gate thin-film transistors (TFTs) in which a gate electrode is located above an active layer.

Referring to FIG. 5, the driving voltage line DVL for supplying the driving voltage EVDD to the sub-pixel SP may be disposed in a first direction. The driving voltage line DVL may be electrically connected to a second electrode E2 of the driving transistor DRT or may be the second electrode E2 of the driving transistor DRT itself. Here, the second electrode E2 of the driving transistor DRT may correspond to the second node N2 of FIG. 4.

Referring to FIG. 5, the driving voltage line DVL may include a first driving voltage line DVLa and a second driving voltage line DVLb. The first driving voltage line DVLa and the second driving voltage line DVLb may be disposed in different layers but electrically connected to each other.

Referring to FIG. 5, the data line DL for supplying the data voltage Vdata corresponding to an image data signal to the sub-pixel SP may be disposed in the first direction. The data line DL may be electrically connected to the drain node or the source node of the scanning transistor SCT.

Referring to FIG. 5, the scanning gate line SCL for supplying the scanning gate signal SCAN to the sub-pixel SP may be disposed in a second direction crossing the first direction. The scanning gate line SCL may be electrically connected to a gate electrode of the scanning transistor SCT and a gate electrode of the sensing transistor SENT. Alternatively, the scanning gate line SCL may be the gate electrode of the scanning transistor SCT itself, and may be the gate electrode of the sensing transistor SENT itself.

Referring to FIG. 5, the driving transistor DRT may include a first electrode E1, the second electrode E2, a third electrode E3, and an active layer ACT.

Referring to FIG. 5, the first electrode E1 may be a source electrode, the second electrode E2 may be a drain electrode, and the third electrode E3 may be a gate electrode. Alternatively, the first electrode E1 may be a drain electrode, the second electrode E2 may be a source electrode, and the third electrode E3 may be a gate electrode. Hereinafter, for convenience of description, a case in which the first electrode E1 is a source electrode, the second electrode E2 is a drain electrode, and the third electrode E3 is a gate electrode will be described as an example.

Referring to FIG. 5, the active layer ACT may include a first region connected to the first electrode E1, a second region connected to the second electrode E2, and a third region between the first region and the second region. The third region of the active layer ACT is a channel region, and may overlap the third electrode E3 corresponding to the gate electrode with an insulating film therebetween.

Referring to FIG. 5, the light shield LS may be disposed below the driving transistor DRT.

Referring to FIG. 5, the storage capacitor Cst may include a first plate PLT1, a second plate PLT2 on the first plate PLT1, and a third plate PLT3 below the first plate PLT1. The first plate PLT1 may be a plate electrically connected to the third electrode E3 of the driving transistor DRT, and may be a conductive region of an active layer ACT_SCT of the scanning transistor SCT. The second plate PLT2 may correspond to the first electrode E1 of the driving transistor DRT. The third plate PLT3 may be the light shield LS electrically connected to the first electrode E1 of the driving transistor DRT.

Referring to FIG. 5, the pixel electrode PE electrically connected to the first electrode E1 of the driving transistor DRT may be disposed in a region of the sub-pixel SP.

Referring to FIG. 5, the region of the sub-pixel SP may include several contact holes CNTg, CNTp, CNTs1, and CNTs2.

A gate contact hole CNTg may be a contact hole in which the third electrode E3, which is the gate electrode of the driving transistor DRT, and the first plate PLT1 are electrically connected. Here, the first plate PLT1 may be a conductive region of the active layer ACT_SCT of the scanning transistor SCT.

A pixel contact hole CNTp may be a contact hole in which the first electrode E1 of the driving transistor DRT and the pixel electrode PE are electrically connected.

A first source contact hole CNTs1 may be a contact hole in which the first electrode E1 of the driving transistor DRT and the light shield LS are electrically connected.

A second source contact hole CNTs2 may be a contact hole in which the first electrode E1 of the driving transistor DRT and a conductive region of an active layer ACT_SENT of the sensing transistor SENT (corresponding to a drain node of the sensing transistor SENT) are electrically connected.

Referring to the planar structure of FIG. 5, in order to form the storage capacitor Cst, the active layer ACT_SCT of the scanning transistor SCT may be used as the first plate PLT1, and the active layer ACT_SCT of the scanning transistor SCT may be made of the same semiconductor material as the active layer ACT of the driving transistor DRT.

Accordingly, a formation region of the storage capacitor Cst may not overlap the active layer ACT of the driving transistor DRT.

Referring to the planar structure of FIG. 5, the pixel contact hole CNTp may be located above the formation region of the storage capacitor Cst. The pixel contact hole CNTp may not overlap the active layer ACT of the driving transistor DRT. Here, the pixel contact hole CNTp may be a contact hole in which the first electrode E1 of the driving transistor DRT and the pixel electrode PE are electrically connected.

According to the contents described above, a length L of a circuit part of the driving transistor DRT is necessarily very long. The circuit part of the driving transistor DRT may include the first to third electrodes E1, E2, and E3 of the driving transistor DRT, the active layer ACT, and the formation region of the storage capacitor Cst.

In the display device 100 according to embodiments of the present disclosure, an increase in the length L of the circuit part of the driving transistor DRT in each sub-pixel SP may be a factor that reduces an aperture ratio. Accordingly, in the following description, a high aperture ratio structure of the sub-pixel SP according to embodiments of the present disclosure will be described.

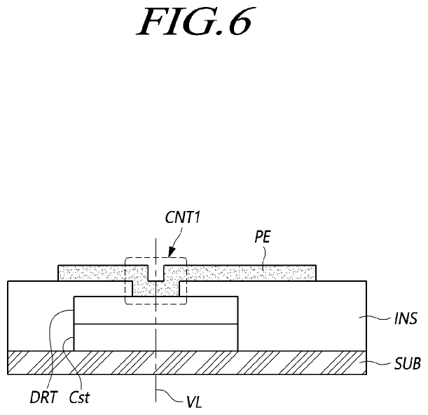

FIG. 6 is a diagram schematically illustrating a high aperture ratio structure of a sub-pixel SP, in a display device 100 according to embodiments of the present disclosure.

A display panel 110 of the display device 100 according to embodiments of the present disclosure in FIG. 6 may include a substrate SUB, and a plurality of sub-pixels SP formed on the substrate SUB.

Each of the plurality of sub-pixels SP may include a driving transistor DRT, a storage capacitor Cst, a pixel electrode PE, and the like.

The driving transistor DRT may be disposed on the substrate SUB and may include a first electrode E1, a second electrode E2, a third electrode E3, and an active layer ACT.

A pixel electrode PE may be disposed on an insulating film INS on the driving transistor DRT, and may be electrically connected to the first electrode E1 of the driving transistor DRT through a first contact hole CNT1 of the insulating film INS. For example, the insulating film INS may include a protective film PAS and an overcoat layer OC to be described below.

The storage capacitor Cst is a capacitor between the first electrode E1 and the third electrode E3.

Referring to FIG. 6, in the sub-pixel SP having a high aperture ratio structure according to embodiments of the present disclosure, the storage capacitor Cst may be formed below the driving transistor DRT.

Referring to FIG. 6, in the sub-pixel SP of the high aperture ratio structure according to embodiments of the present disclosure, the first contact hole CNT1 through which the first electrode E1 of the driving transistor DRT and the pixel electrode PE are electrically connected may be located over the driving transistor DRT.

Referring to FIG. 6, in the sub-pixel SP having a high aperture ratio structure according to embodiments of the present disclosure, the storage capacitor Cst, the active layer ACT, and the first contact hole CNT1 may overlap each other in a vertical direction. In other words, referring to FIG. 6, in the sub-pixel SP having a high aperture ratio structure according to embodiments of the present disclosure, the storage capacitor Cst, the active layer ACT, and the first contact hole CNT1 may be disposed on one vertical line VL.

Referring to FIG. 6, in the sub-pixel SP having a high aperture ratio structure according to embodiments of the present disclosure, the driving transistor DRT may have a bottom gate structure in which a gate electrode E3 is located below the active layer ACT.

However, in the sub-pixel SP having a high aperture ratio structure according to embodiments of the present disclosure, the scanning transistor SCT and the sensing transistor SENT may have a top gate structure in which a gate electrode is located on an active layer.

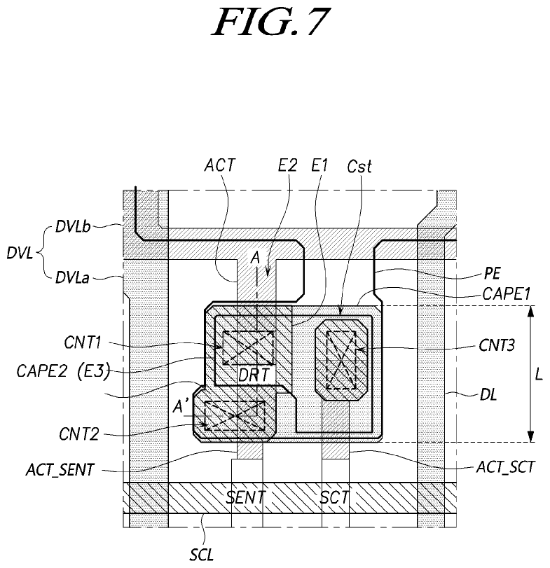

Hereinafter, the high aperture ratio structure of the sub-pixel SP briefly described above will be described in more detail with reference to FIGS. 7 to 10.

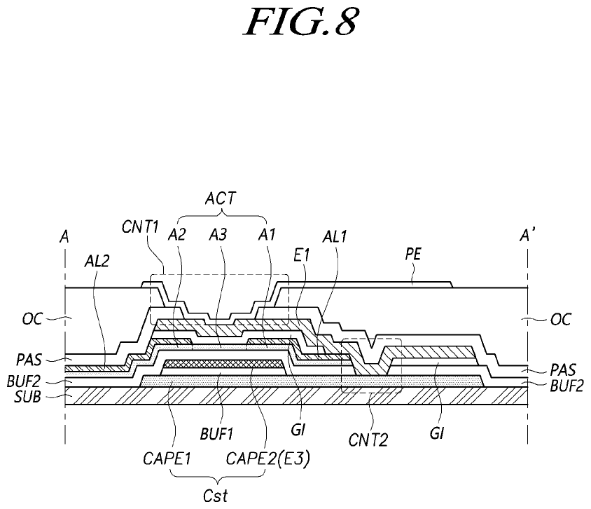

FIG. 7 is a plan view of the display panel 110 in a region in which the sub-pixel SP having a high aperture ratio structure according to embodiments of the present disclosure is disposed, and FIG. 8 is a cross-sectional view taken along line A-A′ of FIG. 7 according to embodiments of the present disclosure.

Referring to FIG. 7, the driving transistor DRT, the scanning transistor SCT, the sensing transistor SENT, and the storage capacitor Cst may be disposed in a region in which one sub-pixel SP is disposed.

Referring to FIG. 7, a driving voltage line DVL for supplying a driving voltage EVDD to the sub-pixel SP may be disposed in the first direction. The driving voltage line DVL may be electrically connected to the second electrode E2 of the driving transistor DRT or may be the second electrode E2 of the driving transistor DRT itself. Here, the second electrode E2 of the driving transistor DRT may correspond to the second node N2 of FIG. 4.

Referring to FIG. 7, the driving voltage line DVL may include a first driving voltage line DVLa and a second driving voltage line DVLb. The first driving voltage line DVLa and the second driving voltage line DVLb may be disposed in different layers, but are electrically connected to each other.

Referring to FIG. 7, a data line DL for supplying a data voltage Vdata corresponding to an image data signal to the sub-pixel SP may be disposed in the first direction. The data line DL may be electrically connected to a drain node or a source node of the scanning transistor SCT.

Referring to FIG. 7, a scanning gate line SCL for supplying a scanning gate signal SCAN to the sub-pixel SP may be disposed in a second direction crossing the first direction. The scanning gate line SCL may be electrically connected to a gate electrode of the scanning transistor SCT and a gate electrode of the sensing transistor SENT. Alternatively, the scanning gate line SCL may be the gate electrode of the scanning transistor SCT itself, and may be the gate electrode of the sensing transistor SENT itself.

Referring to FIG. 7, the driving transistor DRT may include the first electrode E1, the second electrode E2, the third electrode E3, and the active layer ACT. The first electrode E1 may be a source electrode, the second electrode E2 may be a drain electrode, and the third electrode E3 may be a gate electrode. Alternatively, the first electrode E1 may be a drain electrode, the second electrode E2 may be a source electrode, and the third electrode E3 may be a gate electrode. Hereinafter, for convenience of description, a case in which the first electrode E1 is a source electrode, the second electrode E2 is a drain electrode, and the third electrode E3 is a gate electrode will be described as an example.

For example, the source electrode E1 of the driving transistor DRT may include copper (Cu), aluminum (A1), molybdenum (Mo), titanium (Ti), molybdenum-titanium (MoTi), or the like.

For example, the source electrode E1 of the driving transistor DRT may be a single layer or a multi-layer. When the source electrode E1 of the driving transistor DRT is a multi-layer, the source electrode E1 may include a lower source electrode and an upper source electrode.

For example, the lower source electrode may include a first metal, and the upper source electrode may include a second metal. For example, the first metal may include molybdenum (Mo), titanium (Ti), molybdenum-titanium (MoTi), or the like. The second metal may include copper (Cu), aluminum (A1), or the like.

For example, the source electrode E1 of the driving transistor DRT may include the same metal included in the scanning gate line SCL.

Referring to FIGS. 7 and 8, the display panel 110 according to embodiments of the present disclosure may include the substrate SUB, a first capacitor electrode CAPE1 on the substrate SUB, a first buffer layer BUF1 on the first capacitor electrode CAPE1, a second capacitor electrode CAPE2 located on the first buffer layer BUF1 and overlapping at least a portion of the first capacitor electrode CAPE1, a second buffer layer BUF2 on the second capacitor electrode CAPE2, the active layer ACT on the second buffer layer BUF2, a gate insulating film GI on the active layer ACT, and the source electrode E1 located on the gate insulating film GI and overlapping at least a portion of the active layer ACT.

Referring to FIGS. 7 and 8, the display panel 110 according to embodiments of the present disclosure may further include the protective film PAS on the source electrode E1 of the driving transistor DRT, the overcoat layer OC on the protective film PAS, and the pixel electrode PE on the overcoat layer OC.

Referring to FIGS. 7 and 8, in the sub-pixel SP disposed in the display panel 110 according to embodiments of the present disclosure, the active layer ACT of the driving transistor DRT may overlap at least a portion of an overlapping region between the first capacitor electrode CAPE1 and the second capacitor electrode CAPE2.

Accordingly, the storage capacitor Cst configured by the overlap between the first capacitor electrode CAPE1 and the second capacitor electrode CAPE2 is located below the driving transistor DRT, thereby increasing the aperture ratio of the sub-pixel SP.

Referring to FIGS. 7 and 8, the first capacitor electrode CAPE1 and the second capacitor electrode CAPE2 are electrodes that collectively form the storage capacitor Cst. As the first capacitor electrode CAPE1 and the second capacitor electrode CAPE2 overlap each other, the storage capacitor Cst may be formed. That is, the overlapping region between the first capacitor electrode CAPE1 and the second capacitor electrode CAPE2 is a region in which the storage capacitor Cst is formed.

According to the example of FIGS. 7 and 8, an area of the first capacitor electrode CAPE1 may be greater than an area of the second capacitor electrode CAPE2. The second capacitor electrode CAPE2 may be entirely included in a region of the first capacitor electrode CAPE1. That is, all portions of the second capacitor electrode CAPE2 may overlap the first capacitor electrode CAPE1. Accordingly, the overlapping region between the first capacitor electrode CAPE1 and the second capacitor electrode CAPE2 may be the same as a region of the second capacitor electrode CAPE2. Thus, a region in which the storage capacitor Cst is formed may be the same as the region of the second capacitor electrode CAPE2.

For example, the first capacitor electrode CAPE1 may include copper (Cu), aluminum (Al), molybdenum (Mo), titanium (Ti), molybdenum-titanium (MoTi), or the like.

For example, the first capacitor electrode CAPE1 may be a single layer or a multi-layer. When the first capacitor electrode CAPE1 is a multi-layer, the first capacitor electrode CAPE1 may include a first lower capacitor electrode and a first upper capacitor electrode. For example, the first lower capacitor electrode may include a first metal, and the first upper capacitor electrode may include a second metal. For example, the first metal may include molybdenum (Mo), titanium (Ti), molybdenum-titanium (MoTi), or the like. The second metal may include copper (Cu), aluminum (Al), or the like.

For example, the first capacitor electrode CAPE1 may include the same metal included in the first driving voltage line DVLa. The first capacitor electrode CAPE1 may include the same metal included in the data line DL.

For example, the second capacitor electrode CAPE2 may include copper (Cu), aluminum (Al), molybdenum (Mo), titanium (Ti), molybdenum-titanium (MoTi), or the like.

For example, the second capacitor electrode CAPE2 may be a single layer or a multi-layer. When the second capacitor electrode CAPE2 is a multi-layer, the second capacitor electrode CAPE2 may include a second lower capacitor electrode and a second upper capacitor electrode. For example, the second lower capacitor electrode may include a first metal, and the second upper capacitor electrode may include a second metal. For example, the first metal may include molybdenum (Mo), titanium (Ti), molybdenum-titanium (MoTi), or the like. The second metal may include copper (Cu), aluminum (Al), or the like.

For example, the second capacitor electrode CAPE2 may include the same metal included in the gate electrode E3.

For example, the first buffer layer BUF1, the second buffer layer BUF2, and the gate insulating film GI may include various insulating film materials, such as silicon nitride (SiNₓ), silicon dioxide (SiO₂), and the like.

Referring to FIGS. 7 and 8, the active layer ACT of the driving transistor DRT may include a first region A1, a second region A2, and a third region A3 between the first region A1 and the second region A2. That is, in the active layer ACT, the first region A1 may be a region located at one side of the third region A3, and the second region A2 may be a region located on another side of the third region A3.

The active layer ACT of the driving transistor DRT may include a semiconductor material. For example, the active layer ACT of the driving transistor DRT may include an oxide semiconductor material. Here, the oxide semiconductor material may be a semiconductor material in which conductivity is controlled and a band gap is adjusted by performing doping on an oxide material and in general, the oxide semiconductor material may be a transparent semiconductor material having a wide bandgap. For example, the oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), or the like. The active layer ACT may be a single layer or a multi-layer. For example, when the active layer ACT is a multi-layer, the multi-layer may be formed of the same semiconductor material or the multi-layer may be formed of two or more different semiconductor materials.

Referring to FIGS. 7 and 8, the first region A1 and the second region A2 included in an active layer ACT may be conductive regions in which a semiconductor material may be conductorized by a conductorization process. In addition, the third region A3 included in the active layer ACT may be a non-conductive region that maintains its semiconductor properties since a conductorization treatment is not performed thereon. The third region A3 included in the active layer ACT may be a channel region serving as a channel.

Referring to FIGS. 7 and 8, the second capacitor electrode CAPE2 may overlap the third region A3 of the active layer ACT. The third region A3 of the active layer ACT may react according to an electrical state of the second capacitor electrode CAPE2. The second capacitor electrode CAPE2 may correspond to the gate electrode E3 of the driving transistor DRT. Accordingly, an image data signal may be applied to the second capacitor electrode CAPE2.

Referring to FIGS. 7 and 8, the source electrode E1 of the driving transistor DRT may overlap at least a portion of the overlapping region between the first capacitor electrode CAPE1 and the second capacitor electrode CAPE2.

Referring to FIGS. 7 and 8, the source electrode E1 of the driving transistor DRT may overlap the third region A3, which is a channel region of the active layer ACT of the driving transistor DRT.

Referring to FIGS. 7 and 8, the sub-pixel SP having a high aperture ratio structure may include three contact holes CNT1, CNT2, and CNT3.

Referring to FIGS. 7 and 8, the first contact hole CNT1 may be a hole that passes through both the overcoat layer OC and the protective film PAS. In the first contact hole CNT1, the pixel electrode PE and the source electrode E1 of the driving transistor DRT may be electrically connected.

Referring to FIGS. 7 and 8, a second contact hole CNT2 may be a hole that passes through all of the protective film PAS, the gate insulating film GI, and the buffer layers BUF1 and BUF2.

Referring to FIGS. 7 and 8, in the second contact hole CNT2, the source electrode E1 of the driving transistor DRT and the first capacitor electrode CAPE1 may be electrically connected. In addition, in the second contact hole CNT2, the source electrode E1 of the driving transistor DRT and the first region A1 of the active layer ACT of the driving transistor DRT may be electrically connected. In addition, in the second contact hole CNT2, the source electrode E1 of the driving transistor DRT and a conductive region of an active layer ACT_SENT of the sensing transistor SENT may be electrically connected.

Referring to FIG. 7, the active layer ACT of the driving transistor DRT and the active layer ACT_SENT of the sensing transistor SENT may be one active layer. That is, the first region A1 of the active layer ACT of the driving transistor DRT and a first region of the active layer ACT_SENT of the sensing transistor SENT may be the same region.

Referring to FIG. 7, a third contact hole CNT3 may be a contact hole in which the second capacitor electrode CAPE2 corresponding to the gate electrode E3 of the driving transistor DRT and the first region of the active layer ACT_SCT of the scanning transistor SCT are electrically connected. The third contact hole CNT3 may be a hole of the second buffer layer BUF2.

Referring to FIGS. 7 and 8, the source electrode E1 of the driving transistor DRT may be located below the driving transistor DRT and may be electrically connected to the first capacitor electrode CAPE1 located below the active layer ACT. Accordingly, the storage capacitor Cst may be formed below the driving transistor DRT.

The first capacitor electrode CAPE1 may serve as a source electrode below the driving transistor DRT so that the storage capacitor Cst is formed below the driving transistor DRT. In this sense, the first capacitor electrode CAPE1 is also referred to as an auxiliary source electrode or a substitute source electrode.

Referring to FIG. 8, the display panel 110 according to embodiments of the present disclosure may further include the protective film PAS on the source electrode E1 of the driving transistor DRT, the overcoat layer OC on the protective film PAS, and the pixel electrode PE electrically connected to the source electrode E1 of the driving transistor DRT through the first contact hole CNT1 of the protective film PAS and overcoat layer OC.

Referring to FIGS. 7 and 8, in the display panel 110 according to embodiments of the present disclosure, the first contact hole CNT1 corresponding to a pixel contact hole may overlap the active layer ACT of the driving transistor DRT.

Referring to FIGS. 7 and 8, in the display panel 110 according to embodiments of the present disclosure, the first contact hole CNT1 may overlap the third region A3, which is the channel region of the active layer ACT of the driving transistor DRT.

Referring to FIGS. 7 and 8, in the display panel 110 according to embodiments of the present disclosure, the active layer ACT of the driving transistor DRT may include the first region A1, the second region A2, and the third region A3 between the first region A1 and the second region A2.

Referring to FIG. 8, the display panel 110 according to embodiments of the present disclosure may further include a first auxiliary layer AL1 on the first region A1 and a second auxiliary layer AL2 on the second region A2.

The first auxiliary layer AL1 and the second auxiliary layer AL2 on the active layer ACT are channel-defining layers disposed on the first region A1 and the second region A2 except for the third region A3 to define the third region A3, which is the channel region of the active layer ACT.

Referring to FIG. 8, in the display panel 110 according to embodiments of the present disclosure, the active layer ACT of the driving transistor DRT may include a first semiconductor material, and the first auxiliary layer AL1 and the second auxiliary layer AL2 of the driving transistor DRT may include a second semiconductor material different from the first semiconductor material. In this case, the display panel 110 according to embodiments of the present disclosure may be said to have a dual-active layer structure.

Referring to FIG. 8, a mobility of the first semiconductor material included in the active layer ACT of the driving transistor DRT may be greater than a mobility of the second semiconductor material included in the first auxiliary layer AL1 and the second auxiliary layer AL2 of the driving transistor DRT.

For example, the first auxiliary layer AL1 and the second auxiliary layer AL2 of the driving transistor DRT may include a transparent conducting oxide (TCO) as the second semiconductor material. For example, the transparent conducting oxide (TCO) may include one or more of indium zinc oxide (IZO), indium tin oxide (ITO), indium gallium zinc oxide (IGZO), zinc oxide (ZnO), aluminum-doped zinc oxide (AZO), gallium-doped zinc oxide (GZO), antimony tin oxide (ATO), fluorine-doped tin oxide (FTO), and the like.

Referring to FIG. 8, the active layer ACT included in the active layer ACT of the driving transistor DRT may include the first semiconductor material. In contrast, the first auxiliary layer AL1 and the second auxiliary layer AL2 of the driving transistor DRT may include a metal rather than including the second semiconductor material.

For example, the metal included in the first auxiliary layer AL1 and the second auxiliary layer AL2 may include copper (Cu), aluminum (Al), molybdenum (Mo), titanium (Ti), molybdenum-titanium (MoTi), or the like.

For example, the first auxiliary layer AL1 and the second auxiliary layer AL2 may include the same metal included in the source electrode E1. The first auxiliary layer AL1 and the second auxiliary layer AL2 may include the same metal as the metal included in the first capacitor electrode CAPE1 and/or the second capacitor electrode CAPE2.

As described above, three main features of the high aperture ratio structure of the sub-pixel SP according to embodiments of the present disclosure are briefly summarized as follows.

As a first feature, the storage capacitor Cst may be formed below the driving transistor DRT. Here, the storage capacitor Cst may be configured (formed) by the overlap between the first capacitor electrode CAPE1 and the second capacitor electrode CAPE2, and the second capacitor electrode CAPE2 may correspond to the gate electrode E3 of the driving transistor DRT.

As a second feature, the driving transistor DRT may have a bottom gate structure in which the gate electrode E3 is disposed below the active layer ACT. Here, the gate electrode E3 may correspond to the second capacitor electrode CAPE2. The second feature is a feature associated with the first feature.

As a third feature, the pixel electrode PE may be electrically connected to the source electrode E1 at an upper portion of the driving transistor DRT.

Due to the three main features of the high aperture ratio structure of the sub-pixel SP, the length L of the circuit part of the driving transistor DRT in the sub-pixel SP can be significantly shortened (see FIG. 5). Here, the circuit part of the driving transistor DRT may include the first to third electrodes E1, E2, and E3 of the driving transistor DRT, the active layer ACT, and the formation region of the storage capacitor Cst.

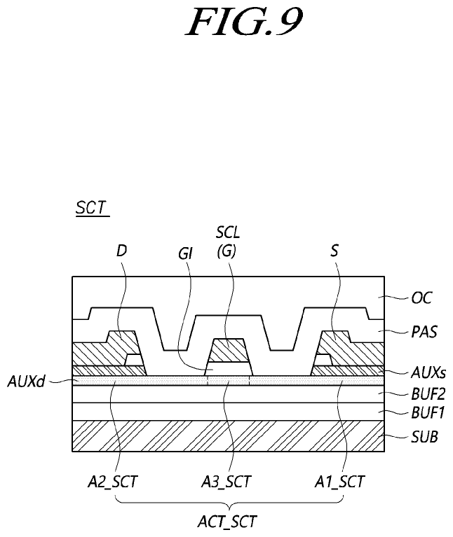

FIG. 9 illustrates a cross-sectional structure of the scanning transistor SCT, in the sub-pixel SP having a high aperture ratio structure according to embodiments of the present disclosure.

Referring to FIG. 9, the sub-pixel SP may further include the scanning transistor SCT in addition to the driving transistor DRT. The scanning transistor SCT may include a drain electrode D, a source electrode S, a gate electrode G, and the active layer ACT_SCT.

Referring to FIG. 9, the drain electrode D or the source electrode S of the scanning transistor SCT may be electrically connected to the data line DL, and the source electrode S or the drain electrode D of the scanning transistor SCT may be electrically connected to the gate electrode E3 of the driving transistor DRT.

Referring to FIG. 9, the gate electrode G of the scanning transistor SCT may be electrically connected to the scanning gate line SCL, or may be a portion of the scanning gate line SCL.

Referring to FIG. 9, in the sub-pixel SP, the driving transistor DRT is a bottom-gate TFT, but the scanning transistor SCT may be a top-gate TFT. The top gate structure of the scanning transistor SCT will be described in more detail below.

Referring to FIG. 9, the active layer ACT_SCT of the scanning transistor SCT may be disposed on the first and second buffer layers BUF1 and BUF2 on the substrate SUB.

Referring to FIG. 9, the active layer ACT_SCT of the scanning transistor SCT may include a first region A1_SCT, a second region A2_SCT, and a third region A3_SCT. The third region A3_SCT may be a channel region disposed between the first region A1_SCT and the second region A2_SCT, and may be a non-conductive region. The first region A1_SCT and the second region A2_SCT may be conductive regions.

Referring to FIG. 9, the source electrode S may be located on the first region A1_SCT of the active layer ACT_SCT of the scanning transistor SCT, and the drain electrode D may be located on the second region A2_SCT of the active layer ACT_SCT of the scanning transistor SCT.

Referring to FIG. 9, the gate insulating film GI may be located on the third region A3_SCT of the active layer ACT_SCT of the scanning transistor SCT, and the gate electrode G or the scanning gate line SCL may be located on the gate insulating film GI. In other words, the third region A3_SCT of the active layer ACT_SCT of the scanning transistor SCT and the gate electrode G or the scanning gate line SCL may overlap each other with the gate insulating film GI interposed therebetween.

Referring to FIG. 9, the protective film PAS and the overcoat layer OC may be disposed on the source electrode S, the drain electrode D, and the gate electrode G.

Referring to FIG. 9, the active layer ACT_SCT of the scanning transistor SCT may be disposed on the same layer as the active layer ACT of the driving transistor DRT. The gate electrode G of the scanning transistor SCT or the gate line SCL corresponding to the gate electrode G of the scanning transistor SCT may be located on the active layer ACT_SCT of the scanning transistor SCT and may be disposed on the same layer as the source electrode E1 of the driving transistor DRT.

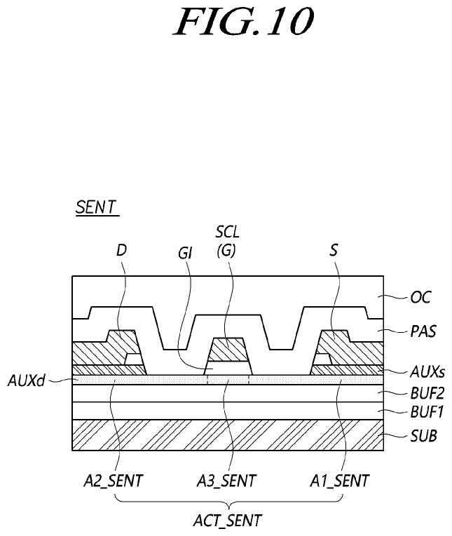

FIG. 10 illustrates a cross-sectional structure of the sensing transistor SENT, in the sub-pixel SP having a high aperture ratio structure according to embodiments of the present disclosure.

Referring to FIG. 10, the sub-pixel SP may further include the sensing transistor SENT in addition to the driving transistor DRT and the scanning transistor SCT. The sensing transistor SENT may include a drain electrode D, a source electrode S, a gate electrode G, and an active layer ACT_SENT.

Referring to FIG. 10, the drain electrode D or the source electrode S of the sensing transistor SENT may be electrically connected to the reference voltage line RVL, and the source electrode S or the drain electrode D of the sensing transistor SENT may be electrically connected to the source electrode E1 of the driving transistor DRT.

Referring to FIG. 10, the gate electrode G of the sensing transistor SENT may be electrically connected to the scanning gate line SCL, or may be a portion of the scanning gate line SCL.

Referring to FIG. 10, in the sub-pixel SP, the driving transistor DRT is a bottom-gate TFT, but the sensing transistor SENT may be a top-gate TFT. The top gate structure of the sensing transistor SENT will described in more detail below.

Referring to FIG. 10, the active layer ACT_SENT of the sensing transistor SENT may be disposed on the first and second buffer layers BUF1 and BUF2 on the substrate SUB.

Referring to FIG. 10, the active layer ACT_SENT of the sensing transistor SENT may include a first region A1_SENT, a second region A2_SENT, and a third region A3_SENT. The third region A3_SENT may be a channel region disposed between the first region A1_SENT and the second region A2_SENT, and may be a non-conductive region. The first region A1_SENT and the second region A2_SENT may be conductive regions.

Referring to FIG. 10, the source electrode S may be located on the first region A1_SENT of the active layer ACT_SENT of the sensing transistor SENT, and the drain electrode D may be located on the second region A2_SENT of the active layer ACT_SENT of the sensing transistor SENT.

Referring to FIG. 10, the gate insulating film GI may be located on the third region A3_SENT of the active layer ACT_SENT of the sensing transistor SENT, and the gate electrode G or the gate line SCL corresponding to the gate electrode G may be located on the gate insulating film GI. In other words, the third region A3_SENT of the active layer ACT_SENT of the sensing transistor SENT and the gate electrode G or the gate line SCL corresponding to the gate electrode G may overlap each other with the gate insulating film GI interposed therebetween.

Referring to FIG. 10, the protective film PAS and the overcoat layer OC may be disposed on the source electrode S, the drain electrode D, and the gate electrode G.

Referring to FIG. 10, the active layer ACT_SENT of the sensing transistor SENT may be disposed on the same layer as the active layer ACT of the driving transistor DRT. The gate electrode G of the sensing transistor SENT or the gate line SCL corresponding to the gate electrode G of the sensing transistor SENT may be located on the active layer ACT_SENT of the sensing transistor SENT and may be disposed on the same layer as the source electrode E1 of the driving transistor DRT.

The driving transistor DRT according to embodiments of the present disclosure described above with reference to FIGS. 7 and 8 may include an auxiliary source electrode CAPE1 on the substrate SUB, the source electrode E1 located over the auxiliary source electrode CAPE1 but spaced apart from the auxiliary source electrode CAPE1, the active layer ACT located between the auxiliary source electrode CAPE1 and the source electrode E1 and including the first region A1, the second region A2, and the third region A3 between the first region A1 and the second region A2, and the gate electrode E3 located between the auxiliary source electrode CAPE1 and the active layer ACT.

The above-described auxiliary source electrode CAPE1 corresponds to the first capacitor electrode CAPE1 of FIGS. 7 and 8. The above-described gate electrode E3 corresponds to the second capacitor electrode CAPE2 of FIGS. 7 and 8.

The first region A1 of the active layer ACT may be electrically connected to the auxiliary source electrode CAPE1 and the source electrode E1, the second region A2 of the active layer ACT may be electrically connected to the drain electrode or may correspond to the drain electrode, and the third region A3 of the active layer ACT may overlap the gate electrode E3.

At least a portion of the auxiliary source electrode CAPE1 may overlap the gate electrode E3.

At least a portion of the auxiliary source electrode CAPE1 may overlap the source electrode E1.

Since the auxiliary source electrode CAPE1 and the gate electrode E3 constitute the storage capacitor Cst, a voltage difference between the auxiliary source electrode CAPE1 and the gate electrode E3 may be maintained for a predetermined time (e.g., one-frame period).

The source electrode E1 may be electrically connected to upper and side surfaces of an end portion of the first region A1 of the active layer ACT, and may be electrically connected to an upper surface of the auxiliary source electrode CAPE1 through the second contact hole CNT2 of the second layer film BUF2 and the gate insulating film GI.

The gate electrode CAPE2 may be disposed in a shape interposed in a space between the source electrode E1 and the auxiliary source electrode CAPE1.

The display device 100 according to embodiments of the present disclosure described above with reference to FIGS. 7 and 8 may include the substrate SUB, the first capacitor electrode CAPE1 on the substrate SUB, the first buffer layer BUF1 on the first capacitor electrode CAPE1, the second capacitor electrode CAPE2 located on the first buffer layer BUF1 and overlapping at least a portion of the first capacitor electrode CAPE1, a second buffer layer BUF2 on the second capacitor electrode CAPE2, the active layer ACT on the second buffer layer BUF2, the gate insulating film GI on the active layer ACT, the source electrode E1 located on the gate insulating film GI and overlapping at least a portion of the active layer ACT, the overcoat layer OC on the source electrode E1, and the pixel electrode PE electrically connected to the source electrode E1 through the first contact hole CNT1 of the overcoat layer OC.

In the display device 100 according to embodiments of the present disclosure, the first contact hole CNT1 may overlap the active layer ACT.

In the display device 100 according to embodiments of the present disclosure, the first contact hole CNT1 may overlap the third region A3 corresponding to the channel region of the active layer ACT.

In the display device 100 according to embodiments of the present disclosure, the active layer ACT may overlap at least a portion of the overlapping region between the first capacitor electrode CAPE1 and the second capacitor electrode CAPE2.

The above-described embodiments of the present disclosure will be briefly described below.

A display device according to embodiments of the present disclosure may include a substrate, a first capacitor electrode on the substrate, a first buffer layer on the first capacitor electrode, a second capacitor electrode located on the first buffer layer and overlapping at least a portion of the first capacitor electrode, a second buffer layer on the second capacitor electrode, an active layer on the second buffer layer, a gate insulating film on the active layer, and a source electrode located on the gate insulating film and overlapping at least a portion of the active layer.

The active layer may overlap at least a portion of an overlapping region between the first capacitor electrode and the second capacitor electrode.

The active layer may include a first region, a second region, and a third region between the first region and the second region.

The second capacitor electrode may be located below the third region and overlap the third region. An image data signal may be applied to the second capacitor electrode. The second capacitor electrode may be a gate electrode of the driving transistor.

The source electrode may overlap at least a portion of the overlapping region between the first capacitor electrode and the second capacitor electrode.

The source electrode may overlap a channel region of the active layer.

The source electrode may be electrically connected to the first capacitor electrode.

The display device according to embodiments of the present disclosure may further include a protective film on the source electrode, an overcoat layer on the protective film, and a pixel electrode electrically connected to the source electrode through a first contact hole of the protective film and overcoat layer.

The first contact hole may overlap the active layer.

The first contact hole may overlap the channel region of the active layer.

The display device according to embodiments of the present disclosure may further include a first auxiliary layer on the first region and a second auxiliary layer on the second region.

As an example, the active layer may include a first semiconductor material, the first auxiliary layer and the second auxiliary layer may include a second semiconductor material different from the first semiconductor material, and a mobility of the first semiconductor material may be higher than a mobility of the second semiconductor material.

As another example, the active layer may include the first semiconductor material, and the first auxiliary layer and the second auxiliary layer may include a metal.

A sub-pixel may include a driving transistor and a storage capacitor, the storage capacitor may be configured by the overlap between the first capacitor electrode and the second capacitor electrode, and the driving transistor may include the active layer, the source electrode, and the second capacitor electrode. The second capacitor electrode may correspond to the gate electrode of the driving transistor.

The sub-pixel may further include a scanning transistor, an active layer of the scanning transistor may be disposed on the same layer as the active layer of the driving transistor, and a gate electrode of the scanning transistor or a scanning gate line corresponding to the gate electrode of the scanning transistor may be located on the active layer of the scanning transistor and may be disposed on the same layer as the source electrode of the driving transistor.

A transistor according to embodiments of the present disclosure may include an auxiliary source electrode on the substrate, a source electrode located over the auxiliary source electrode and spaced apart from the auxiliary source electrode, an active layer located between the auxiliary source electrode and the source electrode and including a first region, a second region, a the third region between the first region and the second region, and a gate electrode located between the auxiliary source electrode and the active layer.

The first region may be electrically connected to the auxiliary source electrode and the source electrode, the second region may be electrically connected to a drain electrode or may correspond to the drain electrode, the third region may overlap the gate electrode, and at least a portion of the auxiliary source electrode may overlap the gate electrode.

At least a portion of the auxiliary source electrode may overlap the source electrode.

A voltage difference between the auxiliary source electrode and the gate electrode may be maintained for a predetermined time.

A display device according to embodiments of the present disclosure may include a substrate, a first capacitor electrode on the substrate, a first buffer layer on the first capacitor electrode, a second capacitor electrode located on the first buffer layer and overlapping at least a portion of the first capacitor electrode, a second buffer layer on the second capacitor electrode, an active layer on the second buffer layer, a gate insulating film on the active layer, a source electrode located on the gate insulating film and overlapping at least a portion of the active layer, an overcoat layer on the source electrode, and a pixel electrode electrically connected to the source electrode through a first contact hole of the overcoat layer.

In the display device according to embodiments of the present disclosure, the first contact hole may overlap the active layer.

In the display device according to embodiments of the present disclosure, the first contact hole may overlap a channel region of the active layer.

In the display device according to embodiments of the present disclosure, the active layer may overlap at least a portion of an overlapping region between the first capacitor electrode and the second capacitor electrode.

A display device according to embodiments of the present disclosure may include a substrate, a driving transistor disposed on the substrate and including a first electrode, a second electrode, a third electrode, and an active layer, a pixel electrode electrically connected to the first electrode in a first contact hole, and a storage capacitor between the first electrode and the third electrode.

In the display device according to embodiments of the present disclosure, the storage capacitor, the active layer, and the first contact hole may overlap in a vertical direction.

According to embodiments of the present disclosure, a sub-pixel having a high aperture ratio structure can be provided.

According to embodiments of the present disclosure, an aperture ratio of a sub-pixel can be increased through a bottom gate structure of a driving transistor.

According to embodiments of the present disclosure, an aperture ratio of a sub-pixel can be increased through a structure in which a storage capacitor is formed below the driving transistor.

According to embodiments of the present disclosure, an aperture ratio of a sub-pixel can be increased through a structure in which a source electrode of a driving transistor and a pixel electrode are connected to each other at an upper portion of the driving transistor.

According to embodiments of the present disclosure, a transistor having a unique structure allowing an aperture ratio of a sub-pixel to be increased can be provided.

According to embodiments of the present disclosure, a high-resolution image can be provided through a high aperture ratio structure of a sub-pixel.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display device comprising:
a substrate;
a first capacitor electrode on the substrate;
a first buffer layer on the first capacitor electrode;
a second capacitor electrode on the first buffer layer, the second capacitor electrode overlapping at least a portion of the first capacitor electrode;
a second buffer layer on the second capacitor electrode;
an active layer on the second buffer layer;
a gate insulating film on the active layer; and
a source electrode on the gate insulating film, the source electrode overlapping at least a portion of the active layer,
wherein the active layer overlaps at least a portion of an overlapping region between the first capacitor electrode and the second capacitor electrode.

2. The display device of claim 1, wherein the active layer includes a first region, a second region, and a third region between the first region and the second region, and the second capacitor electrode is below the third region and overlaps the third region.

3. The display device of claim 1, wherein an image data signal is applied to the second capacitor electrode.

4. The display device of claim 1, wherein the source electrode overlaps at least a portion of the overlapping region between the first capacitor electrode and the second capacitor electrode.

5. The display device of claim 1, wherein the source electrode overlaps a channel region of the active layer.

6. The display device of claim 1, wherein the source electrode is electrically connected to the first capacitor electrode.

7. The display device of claim 1, further comprising:
a protective film on the source electrode;
an overcoat layer on the protective film; and
a pixel electrode electrically connected to the source electrode through a first contact hole in the protective film and the overcoat layer, the first contact hole overlapping the active layer.

8. The display device of claim 7, wherein the first contact hole overlaps a channel region of the active layer.

9. The display device of claim 1, wherein the active layer includes a first region, a second region, and a third region between the first region and the second region, and the display device further comprises:
a first auxiliary layer on the first region; and
a second auxiliary layer on the second region.

10. The display device of claim 9, wherein the active layer includes a first semiconductor material, each of the first auxiliary layer and the second auxiliary layer includes a second semiconductor material different from the first semiconductor material, and a mobility of the first semiconductor material is greater than a mobility of the second semiconductor material.

11. The display device of claim 9, wherein the active layer includes a first semiconductor material, and each of the first auxiliary layer and the second auxiliary layer includes a metal.

12. The display device of claim 1, further comprising a sub-pixel including a driving transistor and a storage capacitor,
wherein the storage capacitor is configured by an overlap between the first capacitor electrode and the second capacitor electrode,
the driving transistor includes the active layer, the source electrode, and the second capacitor electrode, and
the second capacitor electrode corresponds to a gate electrode of the driving transistor.

13. The display device of claim 12, wherein the sub-pixel further comprises a scanning transistor,
wherein an active layer of the scanning transistor is on a same layer as the active layer of the driving transistor, and
a gate electrode of the scanning transistor or a scanning gate line corresponding to the gate electrode of the scanning transistor is on the active layer of the scanning transistor and is on a same layer as the source electrode of the driving transistor.

14. A transistor comprising:
an auxiliary source electrode on a substrate;
a source electrode over the auxiliary source electrode and spaced apart from the auxiliary source electrode;
an active layer between the auxiliary source electrode and the source electrode, the active layer including a first region, a second region, and a third region between the first region and the second region; and
a gate electrode between the auxiliary source electrode and the active layer,
wherein the first region is electrically connected to the auxiliary source electrode and the source electrode, the second region is electrically connected to a drain electrode or corresponds to the drain electrode, the third region overlaps the gate electrode, and at least a portion of the auxiliary source electrode overlaps the gate electrode.

15. The transistor of claim 14, wherein at least a portion of the auxiliary source electrode overlaps the source electrode.

16. The transistor of claim 14, wherein a voltage difference between the auxiliary source electrode and the gate electrode is maintained for a predetermined time.

17. A display device comprising:
a substrate;
a first capacitor electrode on the substrate;
a first buffer layer on the first capacitor electrode;
a second capacitor electrode on the first buffer layer, the second capacitor electrode overlapping at least a portion of the first capacitor electrode;
a second buffer layer on the second capacitor electrode;
an active layer on the second buffer layer;
a gate insulating film on the active layer;
a source electrode on the gate insulating film, the source electrode overlapping at least a portion of the active layer;
an overcoat layer on the source electrode; and
a pixel electrode electrically connected to the source electrode through a first contact hole in the overcoat layer, the first contact hole overlapping the active layer.

18. The display device of claim 17, wherein the first contact hole overlaps a channel region of the active layer.

19. The display device of claim 17, wherein the active layer overlaps at least a portion of an overlapping region between the first capacitor electrode and the second capacitor electrode.

20. A display device comprising:
a substrate;
a driving transistor on the substrate, the driving transistor including a first electrode, a second electrode, a third electrode, and an active layer;
a pixel electrode electrically connected to the first electrode in a first contact hole; and
a storage capacitor between the first electrode and the third electrode,
wherein the storage capacitor, the active layer, and the first contact hole overlap in a vertical direction.
